(19) United States
(12) Patent Application Publication
(10) Pub. No.: US 2023/0311782 A1
(43) Pub. Date: Oct. 5, 2023

(54) MOVABLE STRUCTURE OF DISPLAY DEVICE AND DISPLAY DEVICE

(71) Applicant: Panasonic Intellectual Property Management Co., Ltd., Osaka (JP)

(72) Inventor: Tomohiro SEKIGUCHI, KANAGAWA KEN (JP)

(73) Assignee: Panasonic Intellectual Property Management Co., Ltd., Osaka (JP)

(21) Appl. No.: 18/101,879

(22) Filed: Jan. 26, 2023

(30) Foreign Application Priority Data
Mar. 30, 2022 (JP) 2022-057056

(51) Int. Cl. B60R 11/02; H05K 5/02

(52) U.S. Cl. CPC B60R 11/0235; H05K 5/0234; B60R 2011/0017

(57) ABSTRACT

A movable structure of a display device includes a tilt mechanism and a slide mechanism. The tilt mechanism changes a tilt of a display surface of a display device with respect to a reference surface, and holds the display device with the changed tilt. The slide mechanism moves the display surface of the display device in a back-and-forth direction from the reference surface while keeping the changed tilt, and holds the display device at a position after the moving.

### CROSS-REFERENCE TO RELATED APPLICATIONS

This application is based upon and claims the benefit of priority from Japanese Patent Application No. 2022-057056, filed on Mar. 30, 2022, the entire contents of which are incorporated herein by reference.

### FIELD

The present disclosure relates generally to a movable structure of a display device and a display device.

### BACKGROUND

In recent years, a rear seat entertainment system has been widely used, in which a display device is installed on a back surface of a rear seat or a back surface of a headrest of a vehicle so that an occupant in the rear seat can enjoy various video content during driving. Such a display device for a rear seat entertainment system may include a touch panel stacked on a display surface as an operation switch. In such a display device, it is desirable that the position and orientation of the display surface can be freely adjusted so that the occupant in the rear seat can easily see and operate.

For example, JP-P2009-521268A discloses a display system that is installed on a back surface of a headrest and is able to adjust an orientation of a display surface.

In the display system disclosed in JP-P2009-521268A, the orientation of the display surface can be adjusted, whereas a position of the display surface in a back-and-forth direction cannot be adjusted. Therefore, in a case where a touch panel is incorporated in the display device, operability of the touch panel may deteriorate.

### SUMMARY

A movable structure of a display device according to the present disclosure includes a tilt mechanism and a slide mechanism. The tilt mechanism is configured to change a tilt of a display surface of a display device with respect to a reference surface, and hold the display device with the changed tilt. The slide mechanism is configured to move the display surface of the display device in a back-and-forth direction from the reference surface while keeping the changed tilt, and hold the display device at a position after the moving.

### BRIEF DESCRIPTION OF THE DRAWINGS

FIG. 1 is an external perspective view illustrating an example of a vehicle seat;

FIG. 2A is a side view illustrating an example of a schematic structure of a display device including a movable structure according to a first embodiment;

FIG. 2B is a front view illustrating an example of the schematic structure of the display device including the movable structure according to the first embodiment;

FIG. 3A is a side view illustrating an example of a state in which the display device including the movable structure according to the first embodiment is tilted;

FIG. 3B is a side view illustrating an example of a state in which the display device including the movable structure according to the first embodiment is pulled out to a front side;

FIG. 3C is a side view illustrating an example of a state in which the display device including the movable structure according to the first embodiment is pulled out to the front side and tilted;

FIG. 4A is a side view illustrating an example of a schematic structure of a display device including a movable structure according to a second embodiment;

FIG. 4B is a front view illustrating an example of the schematic structure of the display device including the movable structure according to the second embodiment;

FIG. 5A is a side view illustrating an example of a state in which the display device including the movable structure according to the second embodiment is tilted;

FIG. 5B is a side view illustrating an example of a state in which the display device including the movable structure according to the second embodiment is pulled out to a front side;

FIG. 5C is a side view illustrating an example of a state in which the display device including the movable structure according to the second embodiment is pulled out to the front side and tilted;

FIG. 6A is a side view illustrating an example of a schematic structure of a display device including a movable structure according to a third embodiment;

FIG. 6B is a front view illustrating an example of the schematic structure of the display device including the movable structure according to the third embodiment;

FIG. 7A is a side view illustrating an example of a state in which the display device including the movable structure according to the third embodiment is tilted;

FIG. 7B is a side view illustrating an example of a state in which the display device including the movable structure according to the third embodiment is pulled out to the front side;

FIG. 7C is a side view illustrating an example of a state in which the display device including the movable structure according to the third embodiment is pulled out to the front side and tilted;

FIG. 8A is a side view illustrating an example of a schematic structure of a display device including a movable structure according to a fourth embodiment;

FIG. 8B is a front view illustrating an example of the schematic structure of the display device including the movable structure according to the fourth embodiment;

FIG. 9A is a side view illustrating an example of a state in which the display device including the movable structure according to the fourth embodiment is tilted;

FIG. 9B is a side view illustrating an example of a state in which the display device including the movable structure according to the fourth embodiment is pulled out to a front side;

FIG. 9C is a side view illustrating an example of a state in which the display device including the movable structure according to the fourth embodiment is pulled out to the front side and tilted;

FIG. 10A is a side view illustrating an example of a schematic structure of a display device including a movable structure according to a fifth embodiment;

FIG. 10B is a front view illustrating an example of the schematic structure of the display device including the movable structure according to the fifth embodiment;

FIG. 11A is a side view illustrating an example of a state in which the display device including the movable structure according to the fifth embodiment is tilted;

FIG. 11B is a side view illustrating an example of a state in which the display device including the movable structure according to the fifth embodiment is pulled out to a front side;

FIG. 11C is a side view illustrating an example of a state in which the display device including the movable structure according to the fifth embodiment is pulled out to the front side and tilted;

FIG. 12A is a side view illustrating an example of a schematic structure of a display device including a movable structure according to a sixth embodiment;

FIG. 12B is a front view illustrating an example of the schematic structure of the display device including the movable structure according to the sixth embodiment;

FIG. 13A is a side view illustrating an example of a state in which a display device including a movable structure according to a sixth embodiment is tilted;

FIG. 13B is a side view illustrating an example of a state in which the display device including the movable structure according to the sixth embodiment is pulled out to the front side;

FIG. 13C is a side view illustrating an example of a state in which the display device including the movable structure according to the sixth embodiment is pulled out to the front side and tilted;

FIG. 14A is a side view illustrating an example of a schematic structure of a display device including a movable structure according to a seventh embodiment;

FIG. 14B is a front view illustrating an example of the schematic structure of the display device including the movable structure according to the seventh embodiment;

FIG. 15A is a side view illustrating an example of a state in which the display device including the movable structure according to the seventh embodiment is tilted;

FIG. 15B is a side view illustrating an example of a state in which the display device including the movable structure according to the seventh embodiment is pulled out to the front side;

FIG. 15C is a side view illustrating an example of a state in which the display device including the movable structure according to the seventh embodiment is pulled out to the front side and tilted;

FIG. 16A is a front view illustrating an example of a schematic structure of a display device including a movable structure according to an eighth embodiment; and

FIG. 16B is an external view illustrating an example of a remote controller that controls the display device according to the eighth embodiment.

### DETAILED DESCRIPTION

### First Embodiment

Hereinafter, a movable structure 5a, which is a first embodiment of a display device 10 according to the present disclosure, will be described with reference to the relevant drawings.

Installation State of Display Device

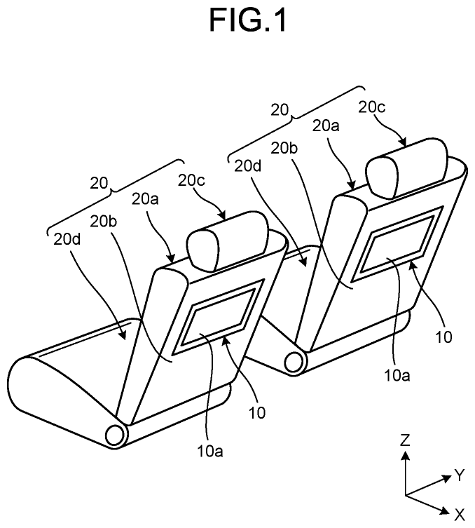

An installation state of the display device 10 will be described with reference to FIG. 1. FIG. 1 is an external perspective view illustrating an example of a vehicle seat.

A vehicle seat 20 includes a seat back 20a, a headrest 20c, and a seat surface 20d. The seat back 20a is a backrest that supports the back of a seated person. The headrest 20c supports the head of the seated person. The seat surface 20d supports the thigh of the seated person.

The display device 10 is installed on a seat back rear surface 20b. The display device 10 includes a display surface 10a. The display device 10 displays various video contents on the display surface 10a. The display device 10 is, for example, a liquid crystal monitor, an organic EL monitor, or the like.

When the display device 10 is not used, the display device 10 is stored in the seat back 20a to follow the seat back rear surface 20b. The seat back rear surface 20b is an example of the reference surface in the present disclosure.

For the description below, the coordinate system XYZ is defined. The X axis is an axis extending from the front to the rear of the seat back 20a. The Y axis is an axis extending from the left to the right of the seat back 20a when viewed from the rear. The Z axis is an axis extending from the lower side to the upper side of the vehicle seat 20.

Note that, while FIG. 1 illustrates an example in which the display device 10 is installed on a back surface of a front seat of the vehicle, the display device 10 may be installed on a back surface of a second seat of the vehicle. In addition, for example, in a case where a large number of seats are connected in a back-and-forth direction as in a bus, the display device 10 may be installed on the back surface of any seat except for the last seat. The following description is given of an optional vehicle seat 20.

Movable Structure of Display Device

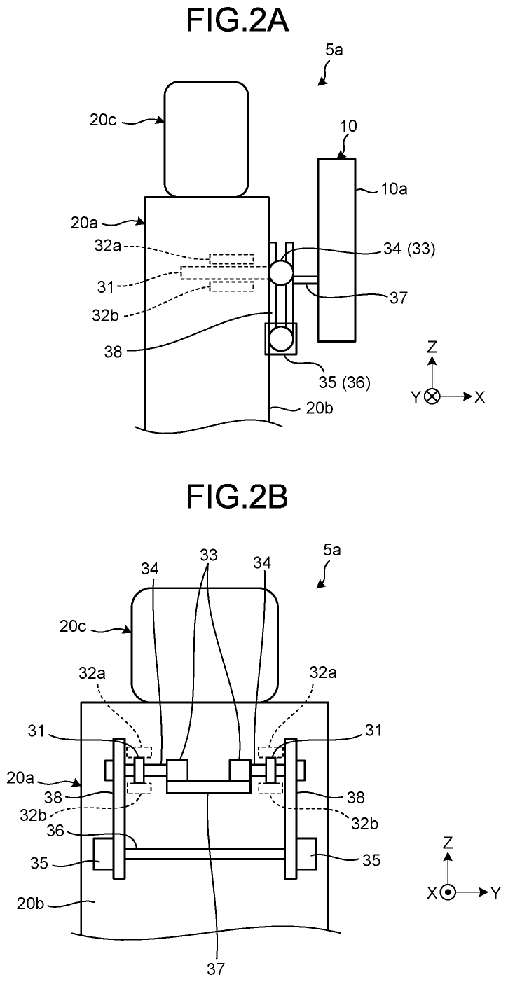

The movable structure 5a according to a first embodiment of a display device 10 will be described with reference to FIGS. 2A and 2B. FIG. 2A is a side view illustrating an example of a schematic structure of a display device including a movable structure according to the first embodiment. FIG. 2B is a front view illustrating an example of a schematic structure of the display device including the movable structure according to the first embodiment.

As illustrated in FIG. 2A, the movable structure 5a of display device 10 includes a slide rail 31, a rail guide 32a, a rail guide 32b, a torque hinge 33, a hinge shaft 34, and a display attachment member 37.

The slide rail 31 is a slide member that is installed inside the seat back 20a and is movable in the back-and-forth direction along the X axis.

The rail guide 32a and the rail guide 32b each support the slide rail 31. When the slide rail 31 moves and then stops, the rail guide 32a and the rail guide 32b keep the position of the slide rail 31 in the X-axis direction by friction torque of a torque hinge 35.

The torque hinge 33 is a hinge member that is connected to an end portion of the slide rail 31 on a positive side of the X axis, that is, an end portion of the slide rail 31 on the side of the display device 10. The torque hinge 33 is capable of changing a rotation angle around the Y axis. The torque hinge 33 generates friction torque. The torque hinge 33 keeps an optional angular position by friction torque. Note that the meaning of the term “connected” includes both a case of being directly connected and a case of being connected via another member. The torque hinge 33 is an example of a first hinge member in the present disclosure.

The hinge shaft 34 is an axis extending from the torque hinge 33 in parallel with a horizontal direction (Y-axis direction in FIG. 2A) of the display surface 10a of the display device 10. That is, the hinge shaft 34 is installed along the Y axis and rotates around the Y axis in accordance with the rotation angle of the torque hinge 33. Note that the hinge shaft 34 is an example of a first hinge shaft in the present disclosure.

The display attachment member 37 is, for example, a plate-like member that connects the torque hinge 33 and the display device 10. Note that the display attachment member 37 is an example of a connection member in the present disclosure.

The movable structure 5a of the display device 10 includes the torque hinge 35, a hinge shaft 36, and an inter-shaft slide link 38.

The torque hinge 35 is a hinge that is installed on the seat back rear surface 20b and is capable of changing an angle between the torque hinge 35 and the seat back rear surface 20b on the XZ plane. The torque hinge 35 generates friction torque and keeps an optional angular position. Note that the torque hinge 35 is an example of a second hinge member in the present disclosure.

The hinge shaft 36 is a shaft member that is connected to the torque hinge 35 and rotates around the Y axis in accordance with the angle between the torque hinge 35 and the seat back rear surface 20b. Note that the hinge shaft 36 is an example of a second hinge shaft in the present disclosure.

A lower end portion of the inter-shaft slide link 38 is connected to the hinge shaft 36 and rotates around the Y axis together with the hinge shaft 36. The inter-shaft slide link 38 slidably holds the hinge shaft 34. The inter-shaft slide link 38 rotates around the Y axis to a position corresponding to the movement of the slide rail 31 in the back-and-forth direction, that is, the movement along the X axis. The inter-shaft slide link 38 is kept at a position after the rotation by friction torque of the torque hinge 33 and the torque hinge 35. The inter-shaft slide link 38 is an example of a slide link in the present disclosure.

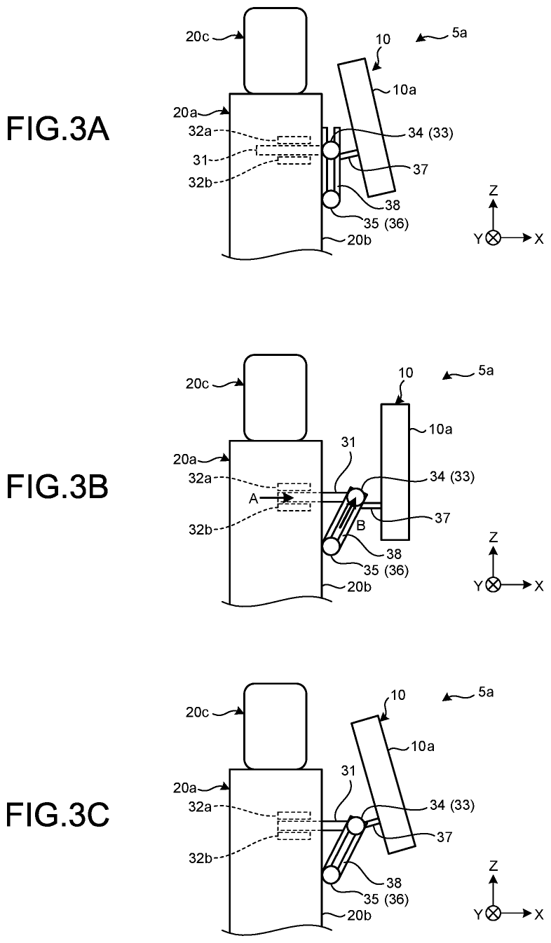

The slide rail 31, the hinge shaft 34, the hinge shaft 36, the torque hinge 35, and the inter-shaft slide link 38 described above constitute a slide mechanism of the display device 10 in the movable structure 5a. The operation of the slide mechanism will be described later in detail (see FIGS. 3B and 3C).

The torque hinge 33, the hinge shaft 34, and the display attachment member 37 constitute a tilt mechanism of the display device 10 in the movable structure 5a. The operation of the tilt mechanism will be described later in detail (see FIGS. 3A and 3C).

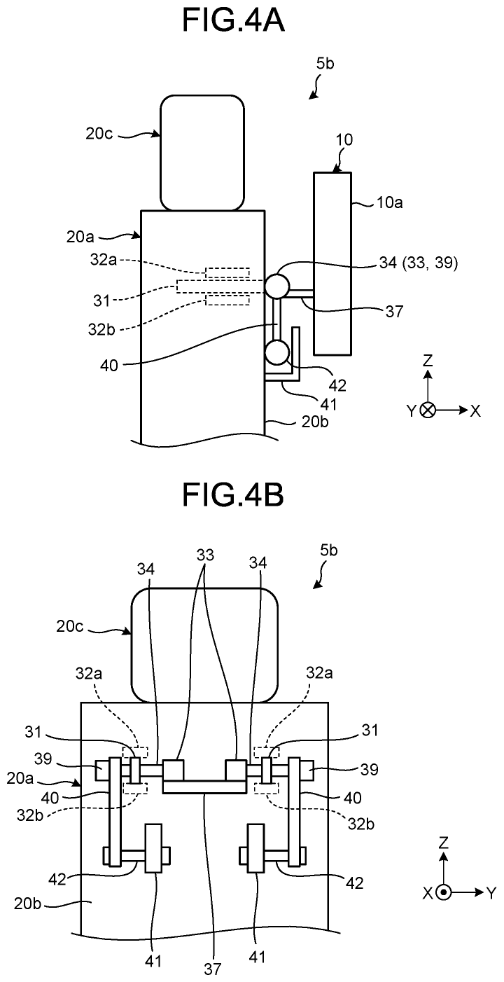

Of the members described with reference to FIG. 2A, members other than hinge shaft 36 and display attachment member 37 are disposed symmetrically at two positions in the Y-axis direction of the seat back 20a as illustrated in FIG. 2B. With this arrangement, the display device 10 attached to the display attachment member 37 is supported in a stable state. Note that the movable structure 5a illustrated in FIGS. 2A and 2B may include a torque hinge 39 illustrated in FIG. 4B, which will be described later, at an end portion of the hinge shaft 34 on a side opposite to a side where the torque hinge 33 is installed. In that case, the tilt mechanism described above also includes the torque hinge 39.

Movable State of Display Device

An example of a movable state by the movable structure 5a according to the first embodiment of the display device 10 will be described with reference to FIGS. 3A, 3B, and 3C. FIG. 3A is a side view illustrating an example of a state in which the display device including the movable structure according to the first embodiment is tilted. FIG. 3B is a side view illustrating an example of a state in which the display device including the movable structure according to the first exemplary embodiment is pulled out to the front side. FIG. 3C is a side view illustrating an example of a state in which the display device including the movable structure according to the first embodiment is pulled out to the front side and tilted.

First, a method for tilting display device 10 will be described with reference to FIG. 3A. When tilting the display device 10, a viewer of the display device 10 rotates a housing of the display device 10 by an optional angle around the Y axis. At this time, the display attachment member 37 rotates around the Y axis together with the display device 10. The end portion of the display attachment member 37 on the side opposite to the display device 10 is connected to the hinge shaft 34, so that the hinge shaft 34 rotates around the Y axis in accordance with the orientation of the display device 10. Moreover, the end portion of the hinge shaft 34 is connected to the torque hinge 33. Thus, a rotational position of the hinge shaft 34, that is, a tilt angle of the display attachment member 37 is kept at a position corresponding to the orientation of the display device 10 by friction torque of the torque hinge 33. Therefore, it is possible for the viewer of the display device 10 to optionally adjust and keep a tilt angle of the display device 10. It can be said that the hinge shaft 34 is an inclination shaft or a tilt shaft that determines the tilt angle of the display device 10.

Next, a method for adjusting a back-and-forth position of the display device 10 will be described with reference to FIG. 3B. When moving the display device 10 in the back-and-forth direction, the viewer of the display device 10 moves the housing of the display device 10 back and forth along the X axis. At this time, the slide rail 31 moves in the back-and-forth direction, that is, along the X axis while being supported by the rail guide 32a and the rail guide 32b. When, for example, the display device 10 is pulled toward the front side, the slide rail 31 moves in a direction of an arrow A. Then, the hinge shaft 34 connected to the end portion of the slide rail 31 slides in a direction of an arrow B between the inter-shaft slide links 38. At this time, the inter-shaft slide link 38 rotates around the hinge shaft 36 and moves in a direction corresponding to the back-and-forth position of the slide rail 31. Then, the position of the slide rail 31 is kept by friction torque of the torque hinge 35. Moreover, the position of the slide rail 31 is kept by friction torque of the torque hinge 35. Therefore, the viewer of the display device 10 can optionally adjust and keep the back-and-forth position of the display device 10.

By performing the operation of FIG. 3A and the operation of FIG. 3B in combination, the movable structure 5a of the display device 10 can hold the display device 10 at an optional tilt angle at an optional back-and-forth position as illustrated in FIG. 3C.

### Operation and Advantage of Embodiment

As described above, the movable structure 5a according to the first embodiment of the display device 10 includes the tilt mechanism and the slide mechanism. The tilt mechanism changes the tilt of the display surface 10a of the display device 10 with respect to the seat back rear surface 20b, and holds the display device 10 with the changed tilt. The slide mechanism moves the display surface 10a of the display device 10 in the back-and-forth direction from the seat back rear surface 20b while keeping the tilt, and holds the display device 10 at a position after the moving. Therefore, the position and orientation of the display surface 10a can be adjusted in accordance with the orientation of the viewer of the display device 10. As a result, for example, in a case where the display device 10 incorporates a touch panel, both the visibility of the display device 10 and the operability of the touch panel can be achieved.

Moreover, in the movable structure 5a according to the first embodiment of the display device 10, the tilt mechanism includes the torque hinge 33, the hinge shaft 34, and the display attachment member 37. The torque hinge 33 is connected to the end portion of the slide rail 31 moving in the back-and-forth direction from the seat back rear surface 20b on the side of the display device 10 and generates friction torque. The hinge shaft 34 extends from the torque hinge 33 in parallel with the horizontal direction of the display surface 10a of the display device 10. The display attachment member 37 connects the hinge shaft 34 and the display device 10. The slide mechanism includes the slide rail 31, the hinge shaft 34, the hinge shaft 36, the torque hinge 35, and the inter-shaft slide link 38. The hinge shaft 36 is installed in parallel with the hinge shaft 34. The torque hinge 35 is connected to an end portion of the hinge shaft 36 and generates friction torque. The inter-shaft slide link 38 rotates and moves together with the hinge shaft 34 and slidably holds the hinge shaft 34 in accordance with the movement of the slide rail 31. Therefore, the position and orientation of the display surface 10a can be adjusted in accordance with the orientation of the viewer of the display device 10.

### Second Embodiment

Hereinafter, a movable structure 5b, which is a second embodiment of the display device 10 according to the present disclosure, will be described with reference to the relevant drawings.

Movable Structure of Display Device

The movable structure 5b according to the second embodiment of the display device 10 will be described with reference to FIGS. 4A and 4B. FIG. 4A is a side view illustrating an example of a schematic structure of the display device including the movable structure according to the second embodiment. FIG. 4B is a front view illustrating an example of the schematic structure of the display device including the movable structure according to the second embodiment.

As illustrated in FIG. 4A, the movable structure 5b of the display device 10 includes a slide rail 31, a rail guide 32a, a rail guide 32b, a torque hinge 33, a hinge shaft 34, and a display attachment member 37. The functions of these structural members are each the same as in the first embodiment.

The movable structure 5b of the display device 10 includes a torque hinge 39, an inter-shaft link 40, a rail member 41, and a sliding shaft 42.

The torque hinge 39 is connected to an end portion of the hinge shaft 34 on a side opposite to the torque hinge 33. The torque hinge 39 keeps an angle between the hinge shaft 34 and the inter-shaft link 40 by friction torque. Note that the torque hinge 39 is an example of a third hinge member in the present disclosure.

The inter-shaft link 40 connects the hinge shaft 34 and the sliding shaft 42 so as to keep a parallel state between them. The inter-shaft link 40 is an example of a link member in the present disclosure.

The rail member 41 holds the sliding shaft 42 slidably along the seat back rear surface 20b in accordance with the movement of the slide rail 31 in the X-axis direction.

The sliding shaft 42 is connected to one end side of the inter-shaft link 40 and installed in parallel with the hinge shaft 34. The sliding shaft 42 is an example of a first shaft member in the present disclosure.

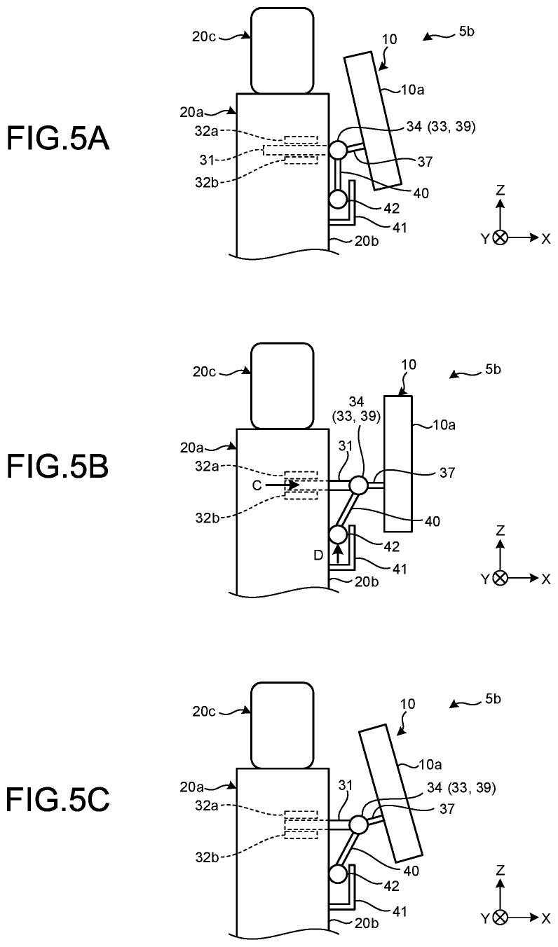

The slide rail 31, the hinge shaft 34, the sliding shaft 42, the inter-shaft link 40, the torque hinge 39, and the rail member 41 constitute a slide mechanism of the display device 10 in the movable structure 5b. The operation of the slide mechanism will be described later in detail (see FIGS. 5B and 5C).

The torque hinge 33, the hinge shaft 34, and the display attachment member 37 constitute a tilt mechanism of the display device 10 in the movable structure 5b. The operation of the tilt mechanism will be described later in detail (see FIGS. 5A and 5C).

Of the members described with reference to FIG. 4A, members other than display attachment member 37 are disposed symmetrically at two positions in the Y-axis direction of the seat back 20a as illustrated in FIG. 4B. Thus, the display device 10 attached to the display attachment member 37 is supported in a stable state.

Movable State of Display Device

An example of the movable state by the movable structure 5b according to the second embodiment of the display device 10 will be described with reference to FIGS. 5A, 5B, and 5C. FIG. 5A is a side view illustrating an example of a state in which the display device including the movable structure according to the second embodiment is tilted. FIG. 5B is a side view illustrating an example of a state in which the display device including the movable structure according to the second embodiment is pulled out to the front side. FIG. 5C is a side view illustrating an example of a state in which the display device including the movable structure according to the second embodiment is pulled out to the front side and tilted.

First, a method for tilting display device 10 will be described with reference to FIG. 5A. When tilting the display device 10, a viewer of the display device 10 rotates a housing of the display device 10 by an optional angle around the Y axis. At this time, the display attachment member 37 rotates around the Y axis together with the display device 10. The end portion of the display attachment member 37 on the side opposite to the display device 10 is connected to the hinge shaft 34, so that the hinge shaft 34 rotates around the Y axis in accordance with the orientation of the display device 10. The end portion of the hinge shaft 34 is connected to the torque hinge 33. Thus, a rotational position of the hinge shaft 34, that is, a tilt angle of the display attachment member 37 is kept at a position corresponding to the orientation of the display device 10 by friction torque of the torque hinge 33. Therefore, the viewer of the display device 10 can optionally adjust and keep a tilt angle of the display device 10.

Next, a method for adjusting the back-and-forth position of the display device 10 will be described with reference to FIG. 5B. When moving the display device 10 in the back-and-forth direction, the viewer of the display device 10 moves the housing of the display device 10 back and forth along the X axis. At this time, the slide rail 31 moves in the back-and-forth direction, that is, along the X axis while being supported by the rail guide 32a and the rail guide 32b. For example, when the display device 10 is pulled out toward the front side, the slide rail 31 moves in the direction of an arrow C. The hinge shaft 34 connected to the end portion of the slide rail 31 moves along the X axis along with the inter-shaft link 40 and the sliding shaft 42. The sliding shaft 42 is sandwiched between the seat back rear surface 20b and the rail member 41. Thus, movement in the X-axis direction is restricted, and the sliding shaft moves in the Z-axis direction, that is, in the direction of an arrow D along the rail member 41. As a result, the inter-shaft link 40 tilts by an amount corresponding to a movement amount of the display device 10 in the X-axis direction. Then, the position of the slide rail 31 after the movement is kept by friction torque of the torque hinge 39. Therefore, the viewer of the display device 10 can optionally adjust and keep the back-and-forth position of the display device 10.

By performing the operation of FIG. 5A and the operation of FIG. 5B in combination, the movable structure 5b of the display device 10 can set and keep the display device 10 in an optional tilt angle direction at an optional back-and-forth position as illustrated in FIG. 5C.

### Operation and Advantage of Embodiment

As described above, in the movable structure 5b according to the second embodiment of the display device 10, the tilt mechanism includes the torque hinge 33, the hinge shaft 34, and the display attachment member 37. The torque hinge 33 is connected to the end portion of the slide rail 31, which moves in the back-and-forth direction from the seat back rear surface 20b, on the side of the display device 10 and generates friction torque. The hinge shaft 34 extends from the torque hinge 33 in parallel with the horizontal direction of the display surface 10a of the display device 10. The display attachment member 37 connects the hinge shaft 34 and the display device 10. Moreover, the slide mechanism includes the slide rail 31, the hinge shaft 34, the sliding shaft 42, the inter-shaft link 40, the torque hinge 39, and the rail member 41. The sliding shaft 42 is installed in parallel with the hinge shaft 34. The inter-shaft link 40 connects the hinge shaft 34 and the sliding shaft 42. The torque hinge 39 is connected to the side of the hinge shaft 34 of the inter-shaft link 40 to generate friction torque and keep an angle between the inter-shaft link 40 and the hinge shaft 34. The rail member 41 holds the sliding shaft 42 slidably along the seat back rear surface 20b in accordance with movement of the slide rail 31. Therefore, the position and orientation of the display surface 10a can be adjusted in accordance with the viewing position of the viewer of the display device 10.

### Third Embodiment

Hereinafter, a movable structure 5c, which is a third embodiment of a display device 10 according to the present disclosure, will be described with reference to the relevant drawings.

Movable Structure of Display Device

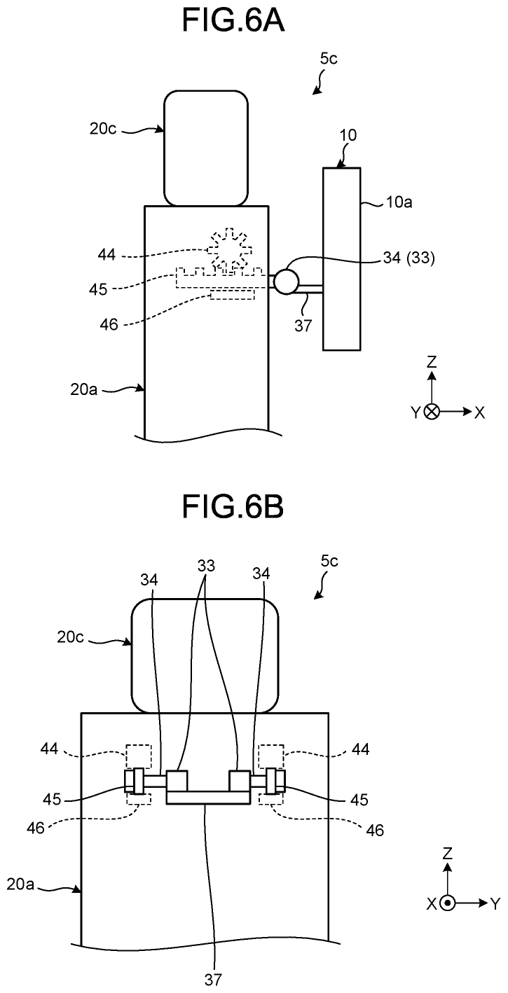

The movable structure 5c according to the third embodiment of the display device 10 will be described with reference to FIGS. 6A and 6B. FIG. 6A is a side view illustrating an example of a schematic structure of the display device including the movable structure according to the third embodiment. FIG. 6B is a front view illustrating an example of the schematic structure of the display device including the movable structure according to the third embodiment.

As illustrated in FIG. 6A, the movable structure 5c of the display device 10 includes a gear 44, a slide rail 45, a rail guide 46, a torque hinge 33, a hinge shaft 34, and a display attachment member 37.

The gear 44 is a cylindrical gear that rotates around the Y axis. The gear 44 generates friction torque.

The slide rail 45 is a rack on which a plate-shaped gear meshing with the gear 44 is formed. The slide rail 45 and the gear 44 form a so-called rack and pinion.

The rail guide 46 is a guide member that holds the slide rail 45.

The torque hinge 33, the hinge shaft 34, and the display attachment member 37 are each the same as in the first embodiment.

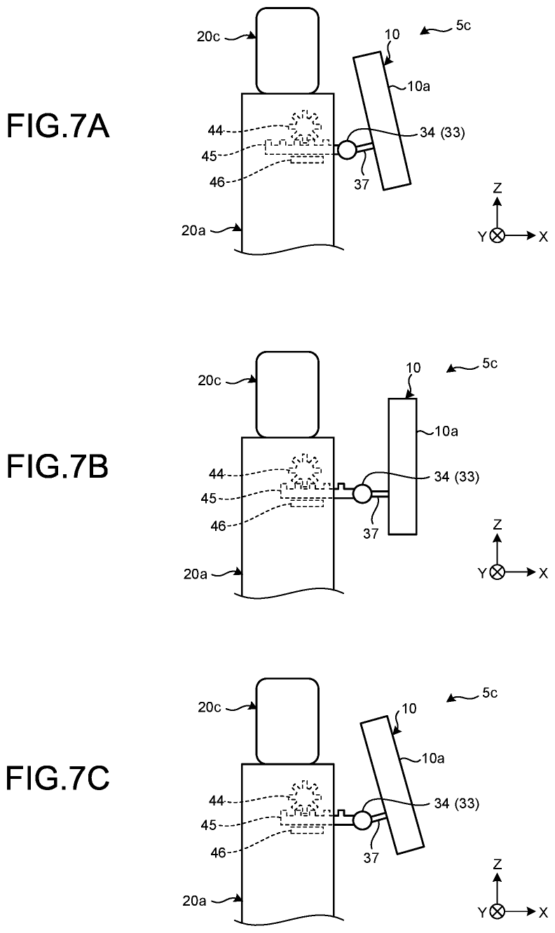

The slide rail 45 and the gear 44 constitute a slide mechanism of the display device 10 in the movable structure 5c. The operation of the slide mechanism will be described later in detail (see FIGS. 7B and 7C).

The torque hinge 33, the hinge shaft 34, and the display attachment member 37 constitute a tilt mechanism of the display device 10. The operation of the tilt mechanism will be described later in detail (see FIGS. 7A and 7C).

Of the members described with reference to FIG. 6A, members other than the display attachment member 37 are disposed symmetrically at two positions in the Y-axis direction of the seat back 20a as illustrated in FIG. 6B. Thus, the display device 10 attached to the display attachment member 37 is supported in a stable state.

Movable State of Display Device

An example of the movable state by the movable structure 5b according to the third embodiment of the display device 10 will be described with reference to FIGS. 7A, 7B, and 7C. FIG. 7A is a side view illustrating an example of a state in which the display device including the movable structure according to the third embodiment is tilted. FIG. 7B is a side view illustrating an example of a state in which the display device including the movable structure according to the third embodiment is pulled out to the front side. FIG. 7C is a side view illustrating an example of a state in which the display device including the movable structure according to the third embodiment is pulled out to the front side and tilted.

First, a method for tilting the display device 10 will be described with reference to FIG. 7A. When tilting the display device 10, a viewer of the display device 10 rotates a housing of the display device 10 by an optional angle around the Y axis. At this time, the display attachment member 37 rotates around the Y axis together with the display device 10. The end portion of the display attachment member 37 on the side opposite to the display device 10 is connected to the hinge shaft 34, so that the hinge shaft 34 rotates around the Y axis in accordance with the orientation of the display device 10. The end portion of the hinge shaft 34 is connected to the torque hinge 33. Thus, a rotational position of the hinge shaft 34, that is, a tilt angle of the display attachment member 37 is kept at a position corresponding to the orientation of the display device 10 by friction torque of the torque hinge 33. Therefore, the viewer of the display device 10 can optionally adjust and keep a tilt angle of the display device 10.

Next, a method for adjusting the back-and-forth position of the display device 10 will be described with reference to FIG. 7B. When moving the display device 10 in the back-and-forth direction, the viewer of the display device 10 moves the housing of the display device 10 back and forth along the X axis. At this time, the slide rail 45 is supported by the rail guide 46 and moves in the back-and-forth direction, that is, along the X axis while being meshed with the gear 44. Then, the position of the slide rail 45 after the movement is kept by friction torque of the gear 44. Therefore, the viewer of the display device 10 can optionally adjust and keep the back-and-forth position of the display device 10.

By performing the operation of FIG. 7A and the operation of FIG. 7B in combination, the movable structure 5c of the display device 10 can set and hold the display device 10 in an optional tilt angle direction at an optional back-and-forth position as illustrated in FIG. 7C.

### Operation and Advantage of Embodiment

As described above, in the movable structure 5c according to the third embodiment of the display device 10, the tilt mechanism includes the torque hinge 33, the hinge shaft 34, and the display attachment member 37. The torque hinge 33 is connected to the end portion of the slide rail 31, which moves in the back-and-forth direction from the seat back rear surface 20b, on the side of the display device 10 and generates friction torque. The hinge shaft 34 extends from the torque hinge 33 in parallel with the horizontal direction of the display surface 10a of the display device 10. The display attachment member 37 connects the hinge shaft 34 and the display device 10. The slide mechanism includes the slide rail 45 and the gear 44. The gear 44 generates friction torque and moves the slide rail 45 in the back-and-forth direction by meshing with the rack formed on the slide rail 45. Therefore, the position and orientation of the display surface 10a can be adjusted in accordance with the viewing position of the viewer of the display device 10.

### Fourth Embodiment

Hereinafter, a movable structure 5d, which is a fourth embodiment of a display device 10 according to the present disclosure, will be described with reference to the relevant drawings.

Movable Structure of Display Device

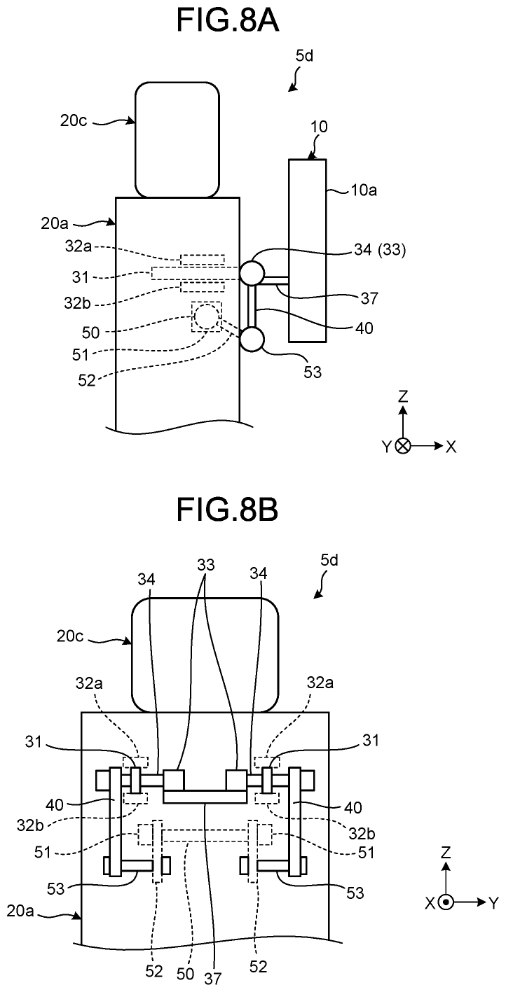

The movable structure 5d according to the fourth embodiment of the display device 10 will be described with reference to FIGS. 8A and 8B. FIG. 8A is a side view illustrating an example of a schematic structure of the display device including the movable structure according to the fourth embodiment. FIG. 8B is a front view illustrating an example of the schematic structure of the display device including the movable structure according to the fourth embodiment.

As illustrated in FIG. 8A, the movable structure 5d of the display device 10 includes a slide rail 31, a rail guide 32a, a rail guide 32b, a torque hinge 33, a hinge shaft 34, and a display attachment member 37. The functions of these structural members are each the same as in the first embodiment.

The movable structure 5d of the display device 10 further includes a hinge shaft 50, a torque hinge 51, an inter-shaft link 52, a connection shaft 53, and an inter-shaft link 40.

The torque hinge 51 is a hinge member that is installed inside the seat back 20a and rotates around the Y axis. The torque hinge 51 generates friction torque and keeps its own position at an optional rotational position.

The hinge shaft 50 is installed along the Y axis from the torque hinge 51, and rotates around the Y axis in accordance with the rotation angle of the torque hinge 51.

The inter-shaft link 52 connects the hinge shaft 50 and the connection shaft 53 so as to keep a parallel state between them.

The connection shaft 53 is a shaft that rotatably connects the inter-shaft link 40 and the inter-shaft link 52.

The inter-shaft link 40 connects the hinge shaft 34 and the connection shaft 53 so as to keep a parallel state between them.

The hinge shaft 50, the torque hinge 51, the inter-shaft link 52, the connection shaft 53, and the inter-shaft link 40 constitute a link mechanism. The link mechanism is deformed into a form corresponding to a position of the slide rail 31 in the back-and-forth direction, in other words, a position of the hinge shaft 34 connected to the end portion of the slide rail 31. Then, in the deformed state, the link mechanism keeps the deformed form by friction torque generated by the torque hinge 33 and the torque hinge 51.

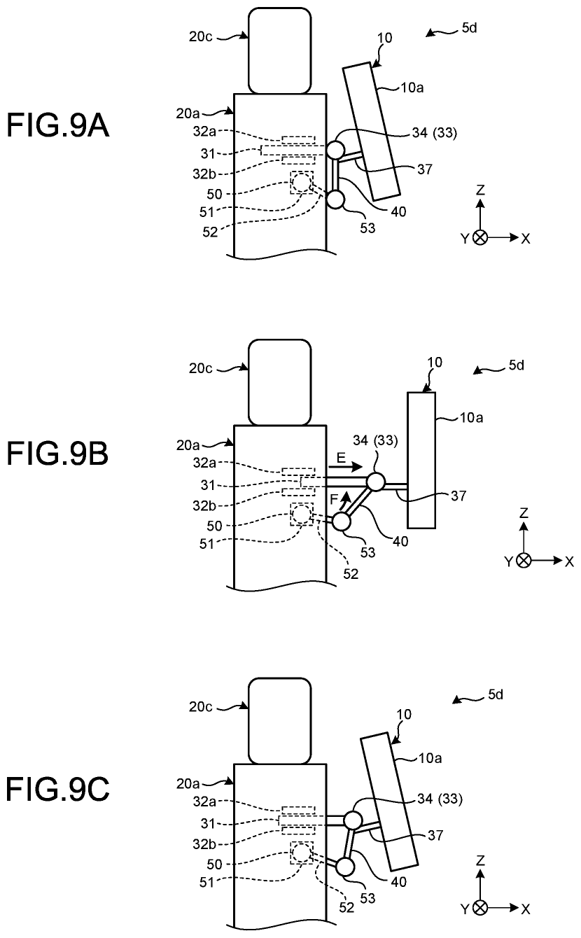

The slide rail 31, the hinge shaft 34, the hinge shaft 50 constituting the link mechanism, the torque hinge 51, the inter-shaft link 52, the connection shaft 53, and the inter-shaft link 40 constitute a slide mechanism of the display device 10 in the movable structure 5d. The operation of the slide mechanism will be described later in detail (see FIGS. 9B and 9C).

The torque hinge 33, the hinge shaft 34, and the display attachment member 37 constitute a tilt mechanism of the display device 10 in the movable structure 5d. The operation of the tilt mechanism will be described later in detail (see FIGS. 9A and 9C).

Of the members described with reference to FIG. 8A, members other than display attachment member 37 and hinge shaft 50 are disposed symmetrically at two positions in the Y-axis direction of the seat back 20a as illustrated in FIG. 8B. Thus, the display device 10 attached to the display attachment member 37 is supported in a stable state. Note that the movable structure 5d illustrated in FIGS. 8A and 8B may include the torque hinge 39 illustrated in FIG. 4B at the end portion of the hinge shaft 34 opposite to the side where the torque hinge 33 is installed. In that case, the tilt mechanism described above also includes the torque hinge 39.

Movable State of Display Device

An example of the movable state by the movable structure 5d according to the fourth embodiment of the display device 10 will be described with reference to FIGS. 9A, 9B, and 9C. FIG. 9A is a side view illustrating an example of a state in which the display device including the movable structure according to the fourth embodiment is tilted. FIG. 9B is a side view illustrating an example of a state in which the display device including the movable structure according to the fourth embodiment is pulled out to the front side. FIG. 9C is a side view illustrating an example of a state in which the display device including the movable structure according to the fourth embodiment is pulled out to the front side and tilted.

First, a method for tilting display device 10 will be described with reference to FIG. 9A. When tilting the display device 10, a viewer of the display device 10 rotates a housing of the display device 10 by an optional angle around the Y axis. At this time, the display attachment member 37 rotates around the Y axis together with the display device 10. The end portion of the display attachment member 37 on the side opposite to the display device 10 is connected to the hinge shaft 34, so that the hinge shaft 34 rotates around the Y axis in accordance with the orientation of the display device 10. The end portion of the hinge shaft 34 is connected to the torque hinge 33. Thus, a rotational position of the hinge shaft 34, that is, a tilt angle of the display attachment member 37 is kept at a position corresponding to the orientation of the display device 10 by friction torque of the torque hinge 33. Therefore, the viewer of the display device 10 can optionally adjust and keep a tilt angle of the display device 10.

Next, a method for adjusting the back-and-forth position of the display device 10 will be described with reference to FIG. 9B. When moving the display device 10 in the back-and-forth direction, the viewer of the display device 10 moves the housing of the display device 10 back and forth along the X axis. At this time, the slide rail 31 moves in the back-and-forth direction, that is, along the X axis while being supported by the rail guides 32a and 32b. For example, when the display device 10 is pulled toward the front side, the slide rail 31 moves in the direction of an arrow E. The hinge shaft 34 connected to the end portion of the slide rail 31 moves along the X axis together with the inter-shaft link 40. As a result, the inter-shaft link 40 moves the connection shaft 53, the inter-shaft link 52, and the hinge shaft 50 in the direction of an arrow F. The form of the link mechanism is deformed. The form of the deformed link mechanism is kept by friction torque of the torque hinge 51, so that the position of the slide rail 31 after the movement is kept. Therefore, the viewer of the display device 10 can optionally adjust and keep the back-and-forth position of the display device 10.

By performing the operation of FIG. 9A and the operation of FIG. 9B in combination, the movable structure 5d of the display device 10 can set and keep the display device 10 at an optional back-and-forth position in a direction of an optional tilt angle as illustrated in FIG. 9C.

### Operation and Advantage of Embodiment

As described above, in the movable structure 5d according to the fourth embodiment of the display device 10, the tilt mechanism includes the torque hinge, the hinge shaft 34, and the display attachment member 37. The torque hinge 33 is connected to the end portion of the slide rail 31, which moves in the back-and-forth direction from the seat back rear surface 20b, on the side of the display device 10 and generates friction torque. The hinge shaft 34 extends from the torque hinge 33 in parallel with the horizontal direction of the display surface 10a of the display device 10. The display attachment member 37 connects the hinge shaft 34 and the display device 10. The slide mechanism includes the slide rail 31, the hinge shaft 34, and a link mechanism. The link mechanism is a mechanism whose one end is connected to the hinge shaft 34 and the other end is installed in the seat back 20a having the seat back rear surface 20b. The link mechanism is deformed into a form corresponding to the position of the slide rail 31 in the back-and-forth direction. Therefore, the position and orientation of the display surface 10a can be adjusted in accordance with the viewing position of the viewer of the display device 10.

### Fifth Embodiment

Hereinafter, a movable structure 5e, which is a fifth embodiment of a display device 10 according to the present disclosure, will be described with reference to the relevant drawings.

Movable Structure of Display Device

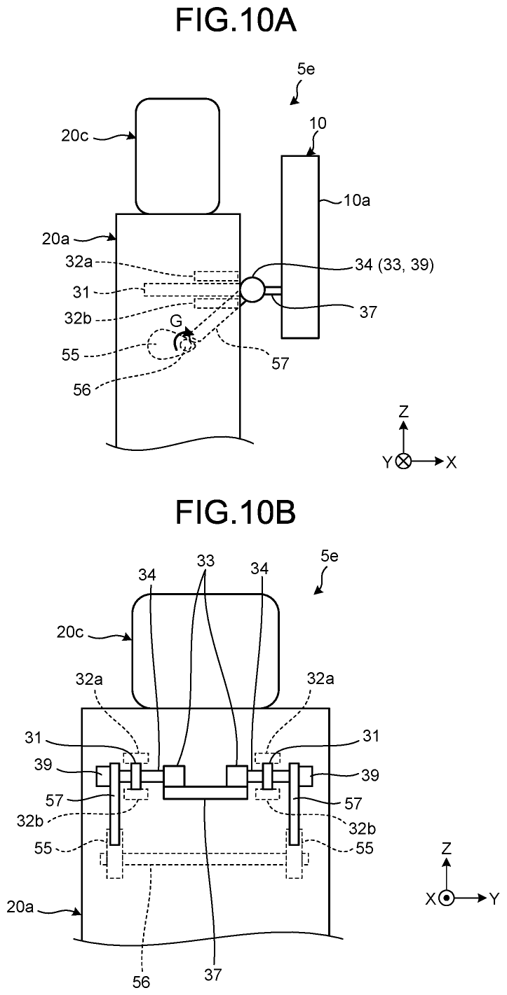

The movable structure 5e according to the fifth embodiment of the display device 10 will be described with reference to FIGS. 10A and 10B. FIG. 10A is a side view illustrating an example of a schematic structure of the display device including the movable structure according to the fifth embodiment. FIG. 10B is a front view illustrating an example of the schematic structure of the display device including the movable structure according to the fifth embodiment.

As illustrated in FIG. 10A, the movable structure 5e of the display device 10 includes a slide rail 31, rail guides 32a and 32b, a torque hinge 33, a hinge shaft 34, and a display attachment member 37. The functions of these structural members are each the same as in the first embodiment.

The movable structure 5e of the display device 10 further includes an eccentric cam 55, a camshaft 56, a cam link 57, and a torque hinge 39.

The eccentric cam 55 is installed in a space (not illustrated in FIGS. 10A and 10B) formed inside the seat back 20a so as to be rotatable around the Y axis. The eccentric cam 55 is biased in the direction of an arrow G by a biasing mechanism (not illustrated). Although a method of realizing the biasing mechanism is not limited, for example, an elastic member such as a helical spring is used. Note that a size of the eccentric cam 55 is determined such that a point farthest from the camshaft 56 on the eccentric cam 55 and the cam link 57 are in contact with each other at a position where the display device 10 is pulled out to the foremost side. In addition, the size of the eccentric cam 55 is determined such that a point closest to the camshaft 56 on the eccentric cam 55 and the cam link 57 are in contact with each other in a state where the display device 10 is retracted to the deepest position.

The camshaft 56 is installed so as to penetrate the eccentric cam 55 along the Y axis. The camshaft 56 supports the eccentric cam 55.

One end of the cam link 57 is connected to the hinge shaft 34, and the other end is biased by the eccentric cam 55 in a direction that makes the hinge shaft 34 apart from the seat back rear surface 20b, that is, in a direction that the slide rail 31 is pulled out toward the positive side on the Y axis.

The cam link 57 is located in a space (not illustrated in FIGS. 10A and 10B) formed inside the seat back 20a. The cam link 57 takes an orientation corresponding to the rotational position of the eccentric cam 55. In addition, it is desirable that a member such as a roller is provided at an end portion on a side where the cam link 57 is in contact with the eccentric cam 55.

In the orientation corresponding to the rotational position of the eccentric cam 55, the cam link 57 overcomes the energization by the eccentric cam 55 by friction torque generated by the torque hinge 33 and keeps that orientation.

The torque hinge 39 is connected to an end portion of the hinge shaft 34 on the side opposite to the torque hinge 33. The torque hinge 39 keeps the orientation of the cam link 57 by friction torque. Note that the torque hinge 39 is an example of a third hinge member in the present disclosure.

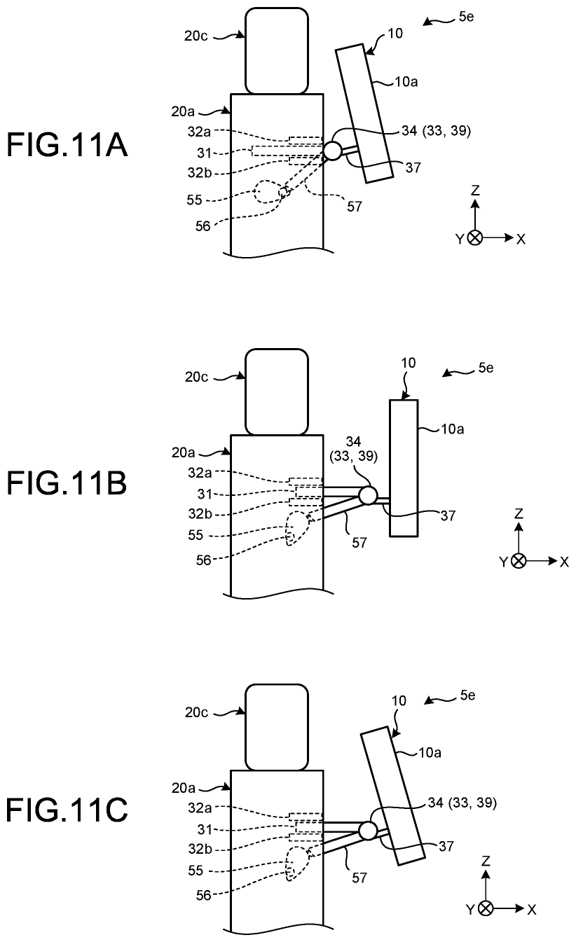

The slide rail 31, the hinge shaft 34, the eccentric cam 55, the cam link 57, and the torque hinge 39 constitute a slide mechanism of the display device 10 in the movable structure 5e. The operation of the slide mechanism will be described later in detail (see FIGS. 11B and 11C).

The torque hinge 33, the hinge shaft 34, and the display attachment member 37 constitute a tilt mechanism of the display device 10 in the movable structure 5e. The operation of the tilt mechanism will be described later in detail (see FIGS. 11A and 11C).

Of the members described in FIG. 10A, members other than display attachment member 37 and camshaft 56 are disposed symmetrically at two positions in the Y-axis direction of the seat back 20a as illustrated in FIG. 10B. Thus, the display device 10 attached to the display attachment member 37 is supported in a stable state.

Movable State of Display Device

An example of the movable state by the movable structure 5e according to the fifth embodiment of the display device 10 will be described with reference to FIGS. 11A, 11B, and 11C. FIG. 11A is a side view illustrating an example of a state in which the display device including the movable structure according to the fifth embodiment is tilted. FIG. 11B is a side view illustrating an example of a state in which the display device including the movable structure according to the fifth embodiment is pulled to the front side. FIG. 11C is a side view illustrating an example of a state in which the display device including the movable structure according to the fifth embodiment is pulled out to the front side and tilted.

First, a method for tilting display device 10 will be described with reference to FIG. 11A. When tilting the display device 10, a viewer of the display device 10 rotates a housing of the display device 10 by an optional angle around the Y axis. At this time, the display attachment member 37 rotates around the Y axis together with the display device 10. The end portion of the display attachment member 37 on the side opposite to the display device 10 is connected to the hinge shaft 34, so that the hinge shaft 34 rotates around the Y axis in accordance with the orientation of the display device 10. The end portion of the hinge shaft 34 is connected to the torque hinge 33. Thus, a rotational position of the hinge shaft 34, that is, a tilt angle of the display attachment member 37 is kept at a position corresponding to the orientation of the display device 10 by friction torque of the torque hinge 33. Therefore, the viewer of the display device 10 can optionally adjust and keep a tilt angle of the display device 10.

Next, a method for adjusting the back-and-forth position of the display device 10 will be described with reference to FIG. 11B. When moving the display device 10 in the back-and-forth direction, the viewer of the display device 10 moves the housing of the display device 10 back and forth along the X axis. At this time, the slide rail 31 moves in the back-and-forth direction, that is, along the X axis while being supported by the rail guides 32a and 32b. The hinge shaft 34 connected to the end portion of the slide rail 31 moves along the X axis along with the cam link 57. As a result, the orientation of the cam link 57 and the rotational position of the eccentric cam 55 are uniquely determined. Then, friction torque generated in the torque hinge 39 overcomes the force of the eccentric cam 55 biasing the cam link 57 and keeps the orientation of the cam link 57. Therefore, the viewer of the display device 10 can optionally adjust and keep the back-and-forth position of the display device 10.

By performing the operation of FIG. 11A and the operation of FIG. 11B in combination, the movable structure 5e of the display device 10 can set and keep the display device 10 at an optional back-and-forth position in a direction of an optional tilt angle as illustrated in FIG. 11C.

### Operation and Advantage of Embodiment

As described above, in the movable structure 5e according to the fifth embodiment of the display device 10, the tilt mechanism includes the torque hinge 33, the hinge shaft 34, and the display attachment member 37. The torque hinge 33 is connected to the end portion of the slide rail 31, which moves in the back-and-forth direction from the seat back rear surface 20b, on the side of the display device 10 and generates friction torque. The hinge shaft 34 extends from the torque hinge 33 in parallel with the horizontal direction of the display surface 10a of the display device 10. The display attachment member 37 connects the hinge shaft 34 and the display device 10. The slide mechanism includes the slide rail 31, the hinge shaft 34, the cam link 57, and the torque hinge 39. The cam link 57 is a member whose one end is connected to the hinge shaft 34 and the other end is biased by the eccentric cam 55 in the direction that makes the hinge shaft 34 apart from the seat back rear surface 20b. The torque hinge 39 generates friction torque and keeps the orientation of the cam link 57. Therefore, the position and orientation of the display surface 10a can be adjusted in accordance with the viewing position of the viewer of the display device 10.

### Sixth Embodiment

Hereinafter, a movable structure 5f, which is a sixth embodiment of a display device 10 according to the present disclosure, will be described with reference to the relevant drawings.

Movable Structure of Display Device

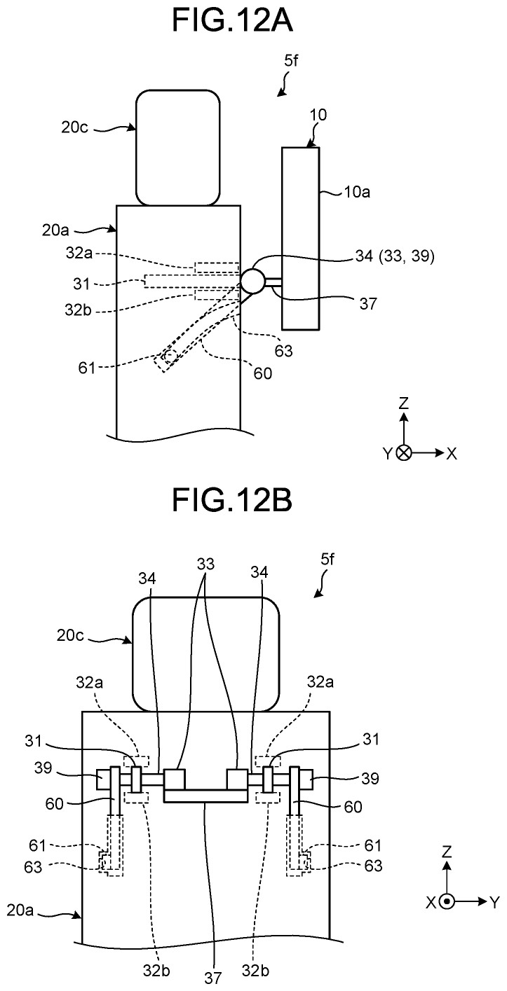

The movable structure 5f according to the sixth embodiment of the display device 10 will be described with reference to FIGS. 12A and 12B. FIG. 12A is a side view illustrating an example of a schematic structure of the display device including the movable structure according to the sixth embodiment. FIG. 12B is a front view illustrating an example of the schematic structure of the display device including the movable structure according to the sixth embodiment.

As illustrated in FIG. 12A, the movable structure 5f of the display device 10 includes a slide rail 31, a rail guide 32a, a rail guide 32b, a torque hinge 33, a hinge shaft 34, and a display attachment member 37. The functions of these structural members are each the same as in the first embodiment.

The movable structure 5f of the display device 10 further includes a slide link 60, a roller 61, a rail groove 63, and a torque hinge 39.

The slide link 60 is a slide member that moves to a position corresponding to the movement of the slide rail 31. One end of the slide link 60 is connected to the hinge shaft 34. The other end of the slide link 60 is inserted into a slide link insertion hole (not illustrated) formed inside the seat back 20a in a direction parallel to the moving direction of the slide rail 31 as viewed from above, that is, in a direction that the negative side on the Z axis is viewed from the positive side on the Z axis. The slide link 60 is an example of a slide member in the present disclosure.

The roller 61 is rotatably connected to the other end of the slide link 60. The roller 61 guides the slide link 60 to a position corresponding to the movement of the slide rail 31 along a rail groove 63 formed along the slide link insertion hole. The roller 61 is an example of a guide member in the present disclosure. The rail groove 63 is an example of a groove in the present disclosure.

The torque hinge 39 is connected to an end portion of the hinge shaft 34 on the side opposite to the torque hinge 33. The torque hinge 39 keeps the orientation of the slide link 60 by friction torque. Note that the torque hinge 39 is an example of a third hinge member in the present disclosure.

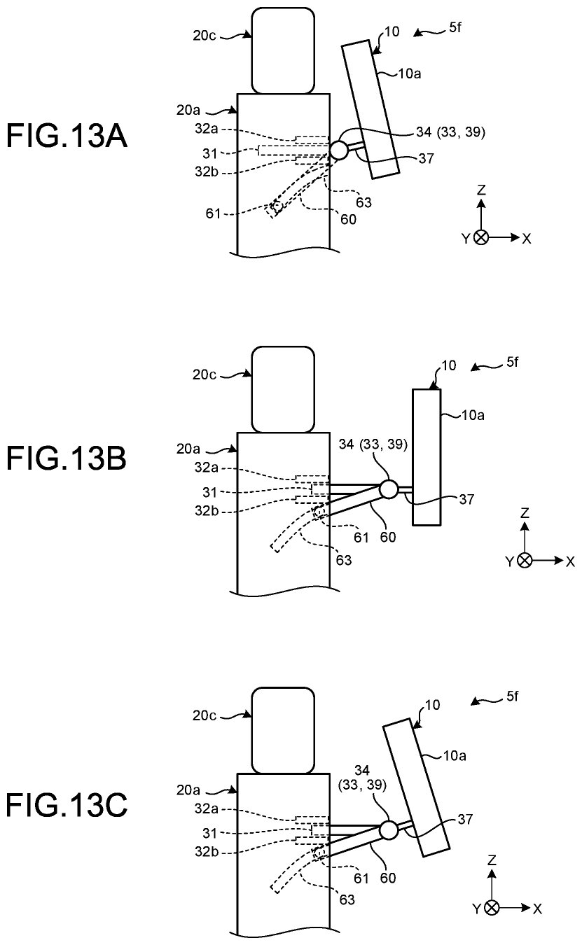

The slide rail 31, the hinge shaft 34, the rail groove 63, the slide link 60, the roller 61, and the torque hinge 39 constitute a slide mechanism of the display device 10 in the movable structure 5f The operation of the slide mechanism will be described later in detail (see FIGS. 13B and 13C).

The torque hinge 33, the hinge shaft 34, and the display attachment member 37 constitute a tilt mechanism of the display device 10 in the movable structure 5f. The operation of the tilt mechanism will be described later in detail (see FIGS. 13A and 13C).

Of the members described in FIG. 12A, members other than the display attachment member 37 are installed symmetrically at two positions in the Y axis direction of the seat back 20a as illustrated in FIG. 12B. With this structure, the display device 10 attached to the display attachment member 37 is supported in a stable state.

Movable State of Display Device

An example of the movable state by the movable structure 5f according to the sixth embodiment of the display device 10 will be described with reference to FIGS. 13A, 13B, and 13C. FIG. 13A is a side view illustrating an example of a state in which the display device including the movable structure according to the sixth embodiment is tilted. FIG. 13B is a side view illustrating an example of a state in which the display device including the movable structure according to the sixth embodiment is pulled out to the front side. FIG. 13C is a side view illustrating an example of a state in which the display device including the movable structure according to the sixth embodiment is pulled out to the front side and tilted.

First, a method for tilting display device 10 will be described with reference to FIG. 13A. When tilting the display device 10, a viewer of the display device 10 rotates a housing of the display device 10 by an optional angle around the Y axis. At this time, the display attachment member 37 rotates around the Y axis together with the display device 10. The end portion of the display attachment member 37 on the side opposite to the display device 10 is connected to the hinge shaft 34, so that the hinge shaft 34 rotates around the Y axis in accordance with the orientation of the display device 10. The end portion of the hinge shaft 34 is connected to the torque hinge 33. Thus, a rotational position of the hinge shaft 34, that is, a tilt angle of the display attachment member 37 is kept at a position corresponding to the orientation of the display device 10 by friction torque of the torque hinge 33. Therefore, the viewer of the display device 10 can optionally adjust and keep a tilt angle of the display device 10.

Next, a method for adjusting the back-and-forth position of the display device 10 will be described with reference to FIG. 13B. When moving the display device 10 in the back-and-forth direction, the viewer of the display device 10 moves the housing of the display device 10 back and forth along the X axis. At this time, the slide rail 31 moves in the back-and-forth direction, that is, along the X axis while being supported by the rail guide 32a and the rail guide 32b. The hinge shaft 34 connected to the end portion of the slide rail 31 moves along the X axis along with the slide link 60. The slide link 60 moves inside a slide link insertion hole 62 (not illustrated) and takes an orientation corresponding to the position of the hinge shaft 34 in the X-axis direction. Then, the slide link 60 keeps its own orientation by friction torque generated in the torque hinge 39. Therefore, the viewer of the display device 10 can optionally adjust and keep the back-and-forth position of the display device 10.

By performing the operation of FIG. 13A and the operation of FIG. 13B in combination, the movable structure 5f of the display device 10 can set and keep the display device 10 at an optional back-and-forth position in a direction of an optional tilt angle as illustrated in FIG. 13C.

### Operation and Advantage of Embodiment

As described above, in the movable structure 5f according to the sixth embodiment of the display device 10, the tilt mechanism includes the torque hinge 33, the hinge shaft 34, and the display attachment member 37. The torque hinge 33 is connected to the end portion of the slide rail 31, which moves in the back-and-forth direction from the seat back rear surface 20b, on the side of the display device 10 and generates friction torque. The hinge shaft 34 extends from the torque hinge 33 in parallel with the horizontal direction of the display surface 10a of the display device 10. The display attachment member 37 connects the hinge shaft 34 and the display device 10. The slide mechanism includes the slide rail 31, the hinge shaft 34, the rail groove 63, the slide link 60, the roller 61, and the torque hinge 39. The rail groove 63 is formed in the seat back 20a having the seat back rear surface 20b in a direction parallel to the moving direction of the slide rail 31 as viewed from above. The slide link 60 is a member whose one end is connected to the hinge shaft 34 and the other end is inserted into the rail groove 63. The other end of the slide link 60 moves to a position corresponding to the movement of the slide rail 31 along the rail groove 63. The roller 61 is connected to the other end of the slide link 60. The roller 61 guides the slide link 60 to a position corresponding to the movement of the slide rail 31 along the rail groove 63. The torque hinge 39 generates friction torque and keeps the orientation of the slide link 60. Therefore, the position and orientation of the display surface 10a can be adjusted in accordance with the viewing position of the viewer of the display device 10.

### Seventh Embodiment

Hereinafter, a movable structure 5g, which is a seventh embodiment of a display device 10 according to the present disclosure, will be described with reference to the relevant drawings.

Movable Structure of Display Device

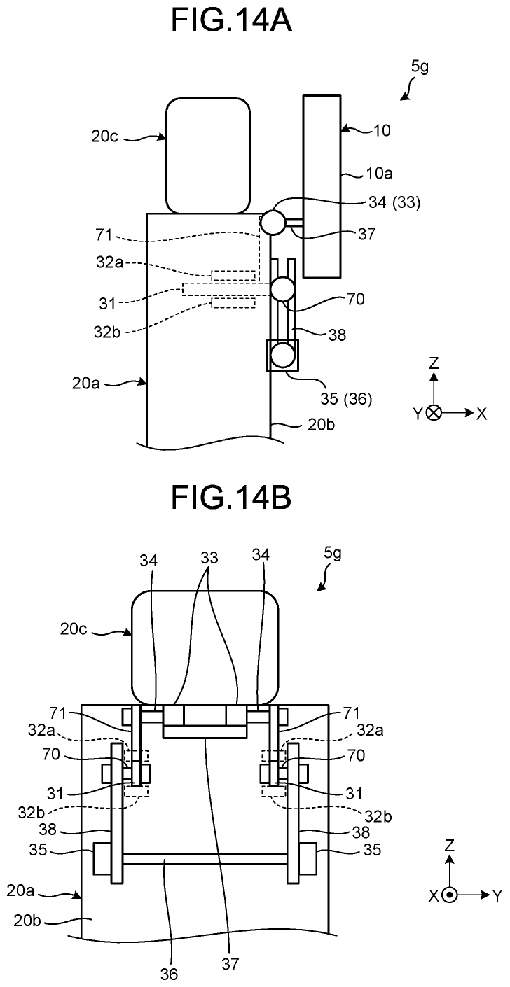

The movable structure 5g according to the seventh embodiment of the display device 10 will be described with reference to FIGS. 14A and 14B. FIG. 14A is a side view illustrating an example of a schematic structure of the display device including the movable structure according to the seventh embodiment. FIG. 14B is a front view illustrating an example of the schematic structure of the display device including the movable structure according to the seventh embodiment.

As illustrated in FIG. 14A, the movable structure 5g of the display device 10 includes a slide rail 31, a rail guide 32a, a rail guide 32b, an offset member 71, a torque hinge 33, a hinge shaft 34, and a display attachment member 37. The offset member 71 is a plate-like member which is connected to an end portion of the slide rail 31 on the positive side in the X axis direction and extends upward along the Z axis. When the slide rail 31 is pushed to the negative side of the X axis, the offset member 71 is buried in seat back 20a. The torque hinge 33 and the hinge shaft 34 are attached to a distal end of the offset member 71 on the positive side on the Z axis along the Y axis. In other words, the torque hinge 33 and the hinge shaft 34 are connected to the end portion of the slide rail 31 on the display device 10 side via the offset member 71. The functions of the structural members other than the offset member 71 are each the same as in the first embodiment.

The movable structure 5g of the display device 10 further includes a slide shaft 70, a torque hinge 35, a hinge shaft 36, and an inter-shaft slide link 38.

The slide shaft 70 is a shaft member connected to an end portion of the slide rail 31 on the positive side of the X axis along the Y axis. The slide shaft 70 moves along the X axis along with the movement of the slide rail 31 in the back-and-forth direction along the X axis and slides inside the inter-shaft slide link 38.

The torque hinge 35, the hinge shaft 36, and the inter-shaft slide link 38 are each the same as in the first embodiment.

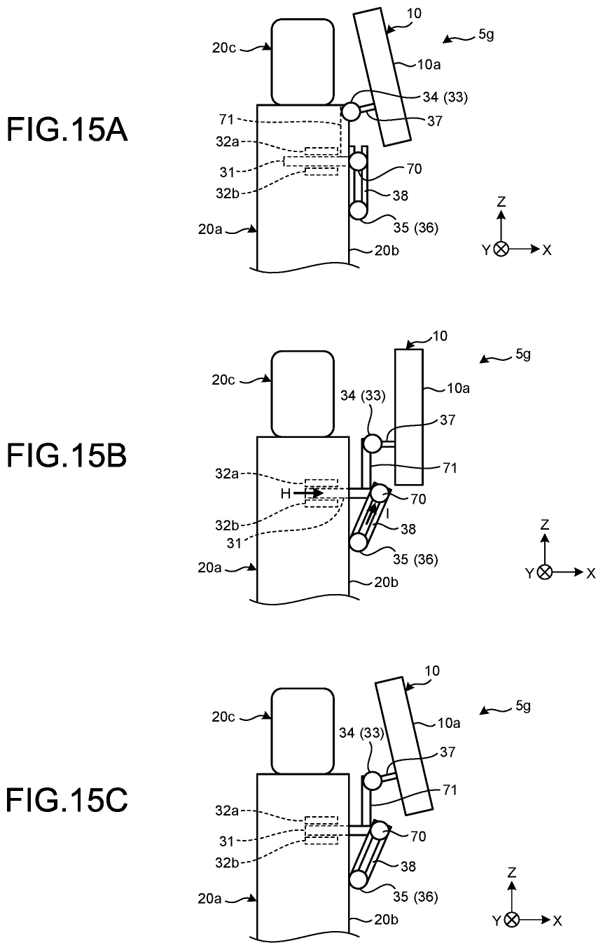

The hinge shaft 34, the hinge shaft 36, the torque hinge 35, the slide shaft 70, and the inter-shaft slide link 38 constitute a slide mechanism of the display device 10 in the movable structure 5g. The operation of the slide mechanism will be described later in detail (see FIGS. 15B and 15C).

The torque hinge 33, the hinge shaft 34, and the display attachment member 37 constitute a tilt mechanism of the display device 10 in the movable structure 5g. The operation of the tilt mechanism will be described later in detail (see FIGS. 15A and 15C).

Of the members described in FIG. 14A, members other than display attachment member 37 and hinge shaft 36 are installed symmetrically at two positions in the Y-axis direction of the seat back 20a as illustrated in FIG. 14B. With this structure, the display device 10 attached to the display attachment member 37 is supported in a stable state.

Movable State of Display Device

An example of the movable state by the movable structure 5g according to the seventh embodiment of the display device 10 will be described with reference to FIGS. 15A, 15B, and 15C. FIG. 15A is a side view illustrating an example of a state in which the display device including the movable structure according to the seventh embodiment is tilted. FIG. 15B is a side view illustrating an example of a state in which the display device including the movable structure according to the seventh embodiment is pulled out to the front side. FIG. 15C is a side view illustrating an example of a state in which the display device including the movable structure according to the seventh embodiment is pulled out to the front side and tilted.

First, a method for tilting display device 10 will be described with reference to FIG. 15A. When tilting the display device 10, a viewer of the display device 10 rotates a housing of the display device 10 by an optional angle around the Y axis. At this time, the display attachment member 37 rotates around the Y axis together with the display device 10. The end portion of the display attachment member 37 on the side opposite to the display device 10 is connected to the hinge shaft 34, so that the hinge shaft 34 rotates around the Y axis in accordance with the orientation of the display device 10. The end portion of the hinge shaft 34 is connected to the torque hinge 33. Thus, a rotational position of the hinge shaft 34, that is, a tilt angle of the display attachment member 37 is kept at a position corresponding to the orientation of the display device 10 by friction torque of the torque hinge 33. Therefore, the viewer of the display device 10 can optionally adjust and keep a tilt angle of the display device 10. The present embodiment has a configuration that the position of the hinge shaft 34, which is the tilt shaft in the first embodiment, is moved to a position offset upward from the end portion of the slide rail 31.

Next, a method for adjusting the back-and-forth position of the display device 10 will be described with reference to FIG. 15B. When moving the display device 10 in the back-and-forth direction, the viewer of the display device 10 moves the housing of the display device 10 back and forth along the X axis. At this time, the slide rail 31 and the offset member 71 move in the back-and-forth direction, that is, along the X axis while being supported by the rail guide 32a and the rail guide 32b. For example, when the display device 10 is pulled to the front side, the slide rail 31 and the offset member 71 move in the direction of an arrow H. The slide shaft 70 connected to the end portion of the slide rail 31 slides in the direction of an arrow I between the inter-shaft slide links 38. At this time, the inter-shaft slide link 38 rotates around the hinge shaft 36 and moves in a direction corresponding to the back-and-forth position of the slide rail 31. Then, the position of the slide rail 31 is kept by friction torque of the torque hinge 35. Therefore, the viewer of the display device 10 can optionally adjust and keep the back-and-forth position of the display device 10.

By performing the operation of FIG. 15A and the operation of FIG. 15B in combination, the movable structure 5g of the display device 10 can set and hold the display device 10 at an optional back-and-forth position in a direction of an optional tilt angle as illustrated in FIG. 15C.

### Operation and Advantage of Embodiment

As described above, in the movable structure 5g according to the seventh embodiment of the display device 10, the tilt mechanism includes the torque hinge 33, the hinge shaft 34, and the display attachment member 37. The torque hinge 33 is connected to the end portion of the slide rail 31, which moves in the back-and-forth direction from the seat back rear surface 20b, on the side of the display device 10 and generates friction torque. The hinge shaft 34 extends from the torque hinge 33 in parallel with the horizontal direction of the display surface 10a of the display device 10. The display attachment member 37 connects the hinge shaft 34 and the display device 10. The slide mechanism includes the slide rail 31, the hinge shaft 34, the hinge shaft 36, the torque hinge 35, and the inter-shaft slide link 38. The hinge shaft 36 is disposed in parallel with the hinge shaft 34. The torque hinge 35 is connected to an end portion of the hinge shaft 36 and generating friction torque. The inter-shaft slide link 38 rotates and moves together with the hinge shaft 34 and slidably holds the hinge shaft 34 in accordance with the movement of the slide rail 31. Therefore, the position and orientation of the display surface 10a can be adjusted in accordance with the viewing position of the viewer of the display device 10.

In addition, in the movable structure 5g according to the seventh embodiment of the display device 10, the torque hinge 33 and the hinge shaft 34 are connected to a position apart from the end portion of the slide rail 31 via the offset member 71. Therefore, by appropriately setting the length of the offset member 71 to suite the vehicle seat 20, an appropriate vertical position of the display device 10 can be adjusted.

Note that the configuration of the present embodiment can be similarly applied to any of the second to sixth embodiments described above.

### Eighth Embodiment

Hereinafter, a movable structure 5h, which is an eighth embodiment of a display device 10 according to the present disclosure, will be described with reference to the relevant drawings.

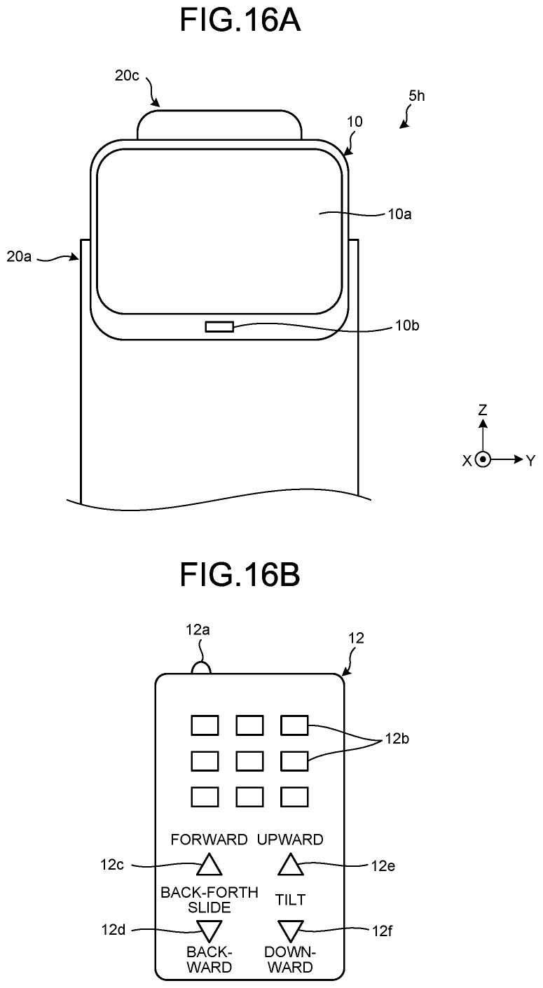

An outline of the movable structure 5h of the display device 10 will be described with reference to FIGS. 16A and 16B. FIG. 16A is a front view illustrating an example of a schematic structure of the display device including the movable structure according to the eighth embodiment. FIG. 16B is an external view illustrating an example of a remote controller that controls the display device according to the eighth embodiment.

The movable structure 5h of the display device 10 according to the eighth embodiment is configured such that an actuator such as an electric motor is incorporated in the movable structure described in the first to seventh embodiments, and the movable structure is electrically moved by a control signal of a remote controller.

That is, as illustrated in FIG. 16A, the movable structure 5h of the display device 10 includes a reception unit 10b on the surface of the display device 10. The reception unit 10b receives a control signal transmitted by a remote controller 12 described later.

Note that, although not illustrated in FIG. 16A, the movable structure 5h of the display device 10 includes an electric motor that moves the slide mechanism of the display device 10, an electric motor that moves the tilt mechanism, a drive circuit of the electric motor, and a control unit that decodes a control signal received by the reception unit 10b and generates a control signal to be input to the drive circuit.

The electric motor that moves the slide mechanism of the display device 10 and the electric motor that moves the tilt mechanism are installed at positions corresponding to the above-described embodiments.

For example, the electric motor that moves the tilt mechanism is desirably attached to, for example, the torque hinge 33 in each embodiment.

Moreover, the electric motor that moves the slide mechanism is desirably attached to the gear 44 in a case of the third embodiment (FIG. 6B). In the other embodiments, it is desirable to attach an electric motor of a linear motor type to the rail guide 32a and the rail guide 32b.

As illustrated in FIG. 16B, the remote controller 12 that controls the slide mechanism and the tilt mechanism of the movable structure 5h of the display device 10 includes a transmission unit 12a, an operation switch 12b, a forward slide switch 12c, a backward slide switch 12d, an upper tilt switch 12e, and a lower tilt switch 12f.

The transmission unit 12a transmits encoded operation signals of various switches.

The operation switch 12b is a switch that gives various operation instructions to the display device 10.

The forward slide switch 12c is a switch that slides the display device 10 forward. For example, while the forward slide switch 12c is continuously pressed, the display device 10 slides forward, that is, slides in the positive direction of the X axis. When the electronic device does not slide forward any more, the electric motor built in the display device 10 stops.

The backward slide switch 12d is a switch that slides the display device 10 backward. For example, the display device 10 slides backward, that is, slides in the negative direction of the X axis while the backward slide switch 12d is continuously pressed. When the electronic device does not slide backward any more, the electric motor built in the display device 10 stops.

The upper tilt switch 12e is a switch that tilts the display device 10 upward. For example, the display device 10 tilts upward, that is, tilts in the positive direction of the Z axis while the upper tilt switch 12e is continuously pressed. When the display device 10 does not tilt upward any more, the electric motor built in the display device stops.

The lower tilt switch 12f is a switch that tilts the display device 10 downward. For example, the display device 10 tilts downward, that is, tilts in the negative direction of the Z axis while the lower tilt switch 12f is continuously pressed. When the display device 10 does not tilt downward any more, the electric motor built in the display device stops.

As described above, in the movable structure 5h according to the eighth embodiment of the display device 10, the movement of the display device 10 by the slide mechanism and the movement of the display device 10 by the tilt mechanism are controlled by the electric motor. Therefore, the viewer can adjust the position and orientation of the display device 10 while sitting on the seat without stretching out his/her hand.

While certain embodiments have been described, these embodiments have been presented by way of example only, and are not intended to limit the scope of the inventions. Indeed, the novel methods and systems described herein may be embodied in a variety of other forms; moreover, various omissions, substitutions and changes in the form of the methods and systems described herein may be made without departing from the spirit of the inventions. The accompanying claims and their equivalents are intended to cover such forms or modifications as would fall within the scope and spirit of the inventions.

According to the movable structure and the display device of the present disclosure, the position and orientation of the display surface can be adjusted in accordance with the viewing position of the viewer.

What is claimed is:

1. A movable structure of a display device, the movable structure comprising:
a tilt mechanism configured to
change a tilt of a display surface of a display device with respect to a reference surface, and
hold the display device with the changed tilt; and
a slide mechanism configured to
move the display surface of the display device in a back-and-forth direction from the reference surface while keeping the changed tilt, and
hold the display device at a position after the moving.

2. The movable structure according to claim 1, wherein
the tilt mechanism includes:
a first hinge member connected to an end portion of a slide rail moving in the back-and-forth direction from the reference surface, the end portion being located on a side of the display device, the first hinge member being configured to generate friction torque;
a first hinge shaft extending from the first hinge member in parallel with a horizontal direction of the display surface of the display device; and
a connection member configured to connect the first hinge shaft and the display device, and
the slide mechanism includes:
the slide rail; and
a gear configured to generate friction torque and move the slide rail in the back-and-forth direction by meshing with a rack on the slide rail.

3. The movable structure according to claim 1, wherein
the tilt mechanism includes:
a first hinge member connected to an end portion of a slide rail moving in the back-and-forth direction from the reference surface, the end portion being located on a side of the display device, the first hinge member being configured to generate friction torque;
a first hinge shaft extending from the first hinge member in parallel with a horizontal direction of the display surface of the display device; and
a connection member configured to connect the first hinge shaft and the display device, and
the slide mechanism includes:
the slide rail;
the first hinge shaft;
a second hinge shaft installed in parallel with the first hinge shaft;
a second hinge member connected to an end portion of the second hinge shaft, the second hinge member being configured to generate friction torque; and
a slide link configured to rotationally move together with the first hinge shaft and slidably hold the first hinge shaft in accordance with movement of the slide rail.

4. The movable structure according to claim 1, wherein
the tilt mechanism includes:
a first hinge member connected to an end portion of a slide rail moving in the back-and-forth direction from the reference surface, the end portion being located on a side of the display device, the first hinge member being configured to generate friction torque;
a first hinge shaft extending from the first hinge member in parallel with a horizontal direction of the display surface of the display device; and
a connection member configured to connect the first hinge shaft and the display device, and
the slide mechanism includes:
the slide rail;
the first hinge shaft;
a first shaft member installed in parallel with the first hinge shaft;
a link member configured to connect the first hinge shaft and the first shaft member;
a third hinge member connected to a side of the first hinge shaft of the link member, the third hinge member being configured to generate friction torque and keep an angle between the link member and the first hinge shaft; and
a rail member configured to hold the first shaft member slidably along the reference surface in accordance with movement of the slide rail.

5. The movable structure according to claim 1, wherein
the tilt mechanism includes:
a first hinge member connected to an end portion of a slide rail moving in the back-and-forth direction from the reference surface, the end portion being located on a side of the display device, the first hinge member being configured to generate friction torque;
a first hinge shaft extending from the first hinge member in parallel with a horizontal direction of the display surface of the display device; and
a connection member configured to connect the first hinge shaft and the display device, and
the slide mechanism includes:
the slide rail;
the first hinge shaft; and
a link mechanism whose one end is connected to the first hinge shaft and the other end is installed in a member constituting the reference surface, the link mechanism being configured to deform into a form corresponding to a position of the slide rail in the back-and-forth direction.

6. The movable structure according to claim 1, wherein
the tilt mechanism includes:
a first hinge member connected to an end portion of a slide rail moving in the back-and-forth direction from the reference surface, the end portion being located on a side of the display device, the first hinge member being configured to generate friction torque;
a first hinge shaft extending from the first hinge member in parallel with a horizontal direction of the display surface of the display device; and
a connection member configured to connect the first hinge shaft and the display device, and
the slide mechanism includes:
the slide rail;
the first hinge shaft;
a cam link whose one end is connected to the first hinge shaft and the other end is biased by an eccentric cam in a direction making the first hinge shaft apart from the reference surface; and
a third hinge member configured to generate friction torque and keep an orientation of the cam link.

7. The movable structure according to claim 1, wherein
the tilt mechanism includes:
a first hinge member connected to an end portion of a slide rail moving in the back-and-forth direction from the reference surface, the end portion being located on a side of the display device, the first hinge member being configured to generate friction torque;
a first hinge shaft extending from the first hinge member in parallel with a horizontal direction of the display surface of the display device; and
a connection member configured to connect the first hinge shaft and the display device, and
the slide mechanism includes:
the slide rail;
the first hinge shaft;
a groove provided in a member constituting the reference surface and provided in a direction parallel to a moving direction of the slide rail as viewed from above;
a slide member whose one end is connected to the first hinge shaft and the other end is inserted into the groove, the other end moving along the groove to a position corresponding to the movement of the slide rail;
a guide member connected to the other end of the slide member, the guide member being configured to guide the slide member to a position corresponding to the movement of the slide rail along the groove; and
a third hinge member configured to generate friction torque and keep an orientation of the slide member.

8. The movable structure according to claim 2, wherein the first hinge member and the first hinge shaft are connected to the slide rail at a position spaced upward from an end portion of the slide rail.

9. The movable structure according to claim 1, wherein movement of the display device by the tilt mechanism and movement of the display device by the slide mechanism are controlled by an actuator.

10. A display device comprising the movable structure according to claim 1.
